(19) United States
(12) Patent Application Publication
(10) Pub. No.: US 2012/0112738 A1
(43) Pub. Date: May 10, 2012

(54) Sensors for Integrated Monitoring and Mitigation of Scour

(75) Inventors: Genda Chen, Rolla, MO (US); David Pommerenke, Rolla, MO (US); Zhi Zhou, Dalian (CN); Ying Huang, Rolla, MO (US)

(73) Assignee: THE CURATORS OF THE UNIVERSITY OF MO, Columbia, MO (US)

(21) Appl. No.: 13/104,682

(22) Filed: May 10, 2011

Related U.S. Application Data
(60) Provisional application No. 61/333,046, filed on May 10, 2010.

(51) Int. Cl. G01R 33/12

(52) U.S. Cl. 324/239

(57) ABSTRACT

Systems and methods for detecting scour. Some embodiments provide systems which include a sensor and a signal generator with a combined density equal to or greater than that of water. Optionally, the sensor can be a magnet, magnetic resonator, or accelerometer. In some embodiments, the sensor is adapted to be placed in regions potentially subject to scour and to sense a scour-related condition. The signal generator generates a wireless signal conveying data regarding the as-sensed scour-related. In some embodiments the sensor is the signal generator while a receiver of the wireless signal can include an antenna, a magnetometer, or an ultrasonic sensor. In some embodiments, the housing is conic and the magnetic object is offset from the center of gravity of the coupled sensor, signal generator and housing.

### CROSS REFERENCE TO RELATED APPLICATIONS

This application claims priority to provisional patent application No. 61/333,046, filed on May 10, 2001, entitled Sensors For Integrated Monitoring And Mitigation Of Scour, and by Dr. Genda Chen the entirety of which is incorporated herein as if set forth in full.

### BACKGROUND

Scour is a process in which a fluid erodes material supporting a structure away from that structure. When scour occurs near a bridge, the associated erosion can cause that bridge to collapse. More particularly, bridge scour is an erosion process in which the current of a river erodes soil deposits around the foundation (piers, abutments, etc.) of a river-crossing bridge. Of course, scour can occur in many bodies of water and near other structures. For instance, bodies of salt water can give rise to scour around piers, walls, levees, etc. More specifically, with bridge scour, portions of the bridge foundation interact with the flow of the river thereby creating eddies and other phenomenon (for instance localized impingement of high speed water on portions of the riverbed) which lead to the erosion. Bridge scour (as well as other forms of scour) is therefore often characterized by the formation of scour holes, dunes, etc. around the bridge foundation.

Scour is a world-wide issue of growing concern. For instance, in the United States, scour-related erosion causes more bridge collapses than any other condition. As of 1997, more than 10,000 bridges out of the 460,000 over-water bridges in the United States were scour critical and 132,000 were scour susceptible. By 2005, however, approximately 26,000 bridges had become scour critical and more than 190,000 bridges had become scour susceptible. With the recent spate of floods, it is likely that even more bridges have become scour critical, potentially resulting in failure of some of these bridges.

### SUMMARY

The following presents a simplified summary in order to provide a basic understanding of some aspects of the disclosed subject matter. This summary is not an extensive overview of the disclosed subject matter, and is not intended to identify key/critical elements or to delineate the scope of such subject matter. A purpose of the summary is to present some concepts in a simplified form as a prelude to the more detailed disclosure that is presented later.

Generally, this document describes embodiments of sensors, systems, and related methods which can help tackle challenges associated with monitoring and mitigating scour. More specifically, one embodiment provides a system for measuring the erosion around bridges caused by scour. These systems can include sensors designed to mimic naturally occurring rocks. This configuration of the sensors enables users to drop the sensors into a river thereby mitigating the scour in some cases.

Generally, embodiments provide systems which work on the following principals (among others):
Passive systems in which the sensors generate a magnetic field or alter the surrounding magnetic field (via a magnet or piece of magnetic material) which is used to detect individual sensors or groups thereof
Passive systems in which the sensors scatter a magnetic field with a resonator using magneto-inductive communication thereby allowing the detection of individual sensors or groups thereof
Active systems in which the sensors have no internal power source. Rather, they receive power through magneto-inductive power coupling to power an active circuit that turns on/off at select times thereby enabling selective transmission of scour related data sensed by the sensors.
Active systems in which the sensors contain an internal power source (for instance, they contain a battery) or receive power from an external magnetic field. Sensors of the current embodiment sense scour related conditions and transmit data regarding the same through magneto-inductive, ultrasonic, or other suitable forms of wireless communication. Some embodiments provide sensors containing a timer so that they can transmit at select times (for instance, every hour). The transmitted data can include data regarding the battery status, an identification of the sensor, the orientation of the sensor, and/or other scour related data.

In some embodiments the sensors contain a magnet (and, optionally, a housing for the magnet) so that the positions of the sensors can be magnetically measured as scour moves the sensors about on the riverbed. In other embodiments, the sensors include active components (in addition to, or in the alternative to, passive magnets) which can detect scour-related condition(s) and can cause information related to scour to be transmitted to a receiver. These active sensors can also be configured to mimic naturally occurring rocks.

Embodiments also provide integrated scour monitoring and mitigation systems. These systems can measure the motion of the sensors as the sensors move about under the influence of liquid in which they are submerged. In some embodiments, the motion of individual sensors is measured whereas in other embodiments the motion of a group of sensors is measured. Whether individual sensors are tracked, or groups of sensors are tracked, the mobility of the sensors can indicate the scour susceptibility/criticality of various monitored structures.

Systems of some embodiments can include a group of such sensors (and other types of sensors if desired), each with an embedded self-inductive device in wireless communication with a measurement instrument (such as a magnetometer). These sensors can also possess densities sufficient to cause them to sink in, yet be moved by, flowing water in a manner similar to naturally occurring rocks (or other filler material). Systems of such embodiments can be used to monitor, prevent, and mitigate riverbed scour-related conditions near bridge foundations. In some embodiments, a user places the sensors near the foundation of a bridge before, after, or even during a scour event. When floods or other scour-inducing events occur, the river current typically moves (or at least re-orients) some of the sensors. As a result of the movement and/or reorientation of the sensors, the three dimensional magnetic field caused by the group of sensors measurably changes. Hence one can observe changes in the magnetic fields during flood conditions, as they indicate movement of sensors, or one can, using many field measurement points reconstruct the location of sensors, without waiting for changes. Changes in the location or orientation of the sensors can be related to characteristics of the scour associated with the bridge foundation. For instance, the as-sensed changes in the magnetic field can be related to the time-varying depth, width, and locations of voids and accumulations of material in or on the riverbed.

Some embodiments provide systems which include a sensor and a signal generator with a combined density equal to or greater than that of water. Optionally, the sensor can be a magnet, resonator, or accelerometer. Moreover, the sensors can be adapted to be placed in regions potentially subject to scour and to sense scour-related conditions. The signal generator of some sensors generates a wireless signal conveying data regarding the as-sensed scour-related. In some embodiments the sensor is the signal generator while a receiver for the wireless signal can include an antenna, a magnetometer, or an ultrasonic sensor. In some embodiments, the housing is conic and the magnetic object is offset from the center of gravity of the coupled sensor, signal generator and housing.

In methods implemented in conjunction with various embodiments, sensors can be placed near existing bridges shortly before (for instance, about one day before) a predicted flood or other scour-inducing event. Since sensors of various embodiments can be dropped into place (or otherwise positioned) and their movements and orientations tracked, such techniques can allow real-time and cost-effective monitoring of scour. Thus, systems of various embodiments can facilitate evaluation of the scour-related condition of bridge foundations and can enable damage reduction, mitigation, prevention, etc. Sensors of various embodiment and/or other types of scour sensors can be applied to many structures (for instance, sea-crossing bridges, levees, pipes undersea cables, etc.) with results similar to those disclosed above. Should scour be detected, sensors and other filler material (artificial objects, naturally occurring rocks, etc.) can be placed near a scour critical (or other) structure to stabilize it based on real-time, reliable, and robust data obtained from various sensors.

Yet other embodiments provide methods of monitoring and/or mitigating scour. In some of these methods, at least one sensor with a density about equal to or greater than water (for instance densities between about 1.2 g/cm̂3 and about 5.3. g/cm̂3) is placed in water at a location where the water is expected to flow and (potentially) cause scour. The sensor includes an object which alters the magnetic field in its vicinity in response to a change in a scour-related condition at about the location of the sensor. Additionally, such methods include allowing a scour-related change to occur at or near the sensor and allowing the sensor to cause a wireless signal to propagate through the water to convey data regarding the scour-related condition.

In some methods the sensor can include a signal generator in communication with the sensor to cause (or transmit) the wireless signal. The signal generator can be a passive magnet, an actively powered magnet, a magnetic resonator, an accelerometer or a combination thereof with, or without, other types of instruments. If desired, the object can be the signal generator. Moreover, in methods of some embodiments, the wireless signal is received and the data conveyed thereby is correlated to determine the scour-related condition.

To the accomplishment of the foregoing and related ends, certain illustrative aspects are described herein in connection with the following description and the associated figures. These aspects are indicative of various ways in which the disclosed subject matter may be practiced, all of which are intended to be within the scope of the disclosed subject matter. Other advantages and novel and non-obvious features may become apparent from the following detailed description when considered in conjunction with the figures.

### BRIEF DESCRIPTION OF THE FIGURES

The detailed description is written with reference to accompanying figures. In the figures, the left-most digit(s) of a reference number identifies the figure in which the reference number first appears. The use of the same reference numbers in different figures indicates similar or identical items.

FIG. 1 illustrates an integrated scour measurement and mitigation system.

FIG. 2 illustrates causes of bridge collapse.

FIG. 3 illustrates growth in the number of scour susceptible bridges.

FIG. 4 illustrates scour associated with a bridge.

FIG. 5 illustrates a comparison of various scour measurement systems.

FIG. 6 illustrates a passive scour measurement and mitigation system.

FIGS. 7A-7D illustrate position response functions of some passive scour sensors.

FIG. 8 illustrates signal intensity-distance curves associated with passive scour sensors made of various materials.

FIG. 9 illustrates an active scour measurement and mitigation system.

### DETAILED DESCRIPTION

This document discloses techniques and technologies for monitoring scour-related conditions. More particularly, this document discloses techniques and technologies for integrated monitoring and mitigation of hydraulic scour associated with bridge foundations and other structures (for instance levees).

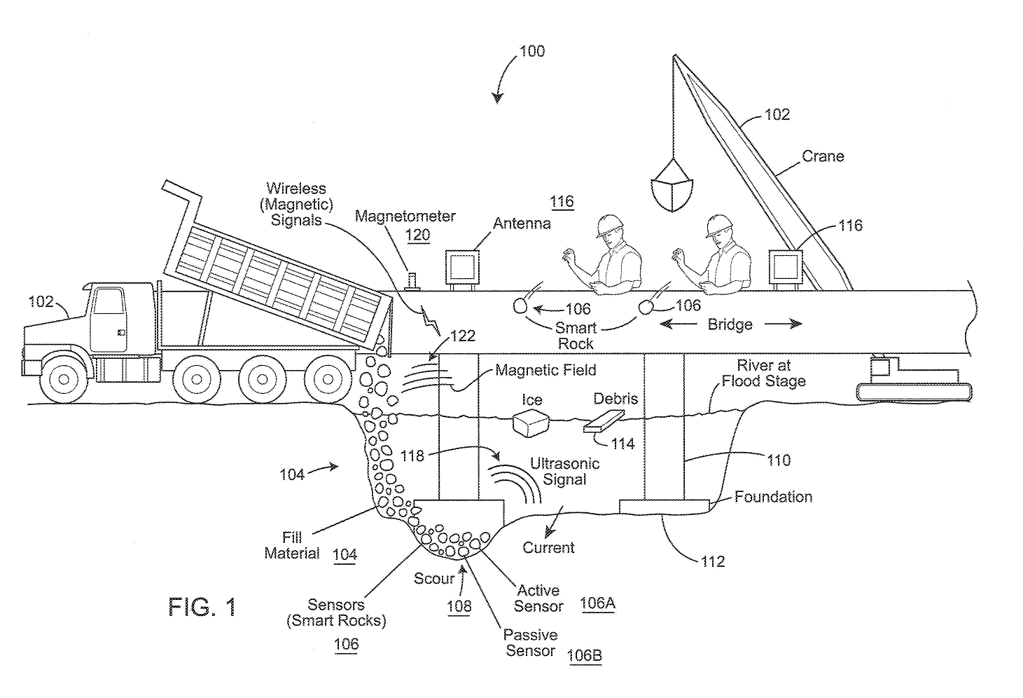

FIG. 1 illustrates an integrated scour measurement and mitigation system. The system 100 of the current embodiment provides integrated scour monitoring and mitigation. As illustrated by FIG. 1, a vehicle 102 (for instance, a truck, barge, crane, etc.) can deposit a volume of filler material 104 including various sensors 106 (for instance, active and passive sensors 106A and 106B respectively) in place near a potential or existing region 108 of scour. In the situation illustrated by FIG. 1, one pier 110 and footing 112 of a bridge foundation has experienced some scour during an ongoing flood. Since the flood waters might be carrying various pieces of debris 114, ice, and the like, it is difficult, if not impossible, to apply previously available scour monitoring technologies to the bridge. Nonetheless, the vehicle 102 is able to position the filler material 104 and sensors 106 (active and passive sensors 106A and 106B in this scenario) in the region 108 undergoing scour.

For the illustrated situation, scour has occurred close enough to shore that a truck can deliver the filler material 104 and sensors 106 to the scour site. If the scour had occurred further from shore or at some other location inaccessible to a truck, then a crane, barge, or other device could be used to deliver the filler material 104 and sensors 106 to the site. Moreover, users can drop additional sensors 106 into the water at the region 108 of interest as is shown in FIG. 1 where the users are dropping the sensors 106 into the water on the upstream side of the bridge. Thus, should the sensors 106 be misplaced, the current is more likely than not to wash the sensors 106 into the scour site.

These users have also deployed a pair of antennas 116 to receive wireless magnetic signals 118 from the sensors 106. In addition, in this case, the users have deployed a magnetometer 120 to sense the magnetic field 122 associated with the passive sensors 106B. As disclosed further herein, though, other communication methods can be employed. For instance, the sensors 106 can use ultrasonic communication, can back scatter RF signals using resonators at the same frequency or at the frequencies of the resonators (positioned in various receiving devices located on shore or elsewhere). From the data gathered by the antennas 116 and the magnetometer 120, the users can derive information related to the location and dimensions of various scour-related voids and formations near the bridge.

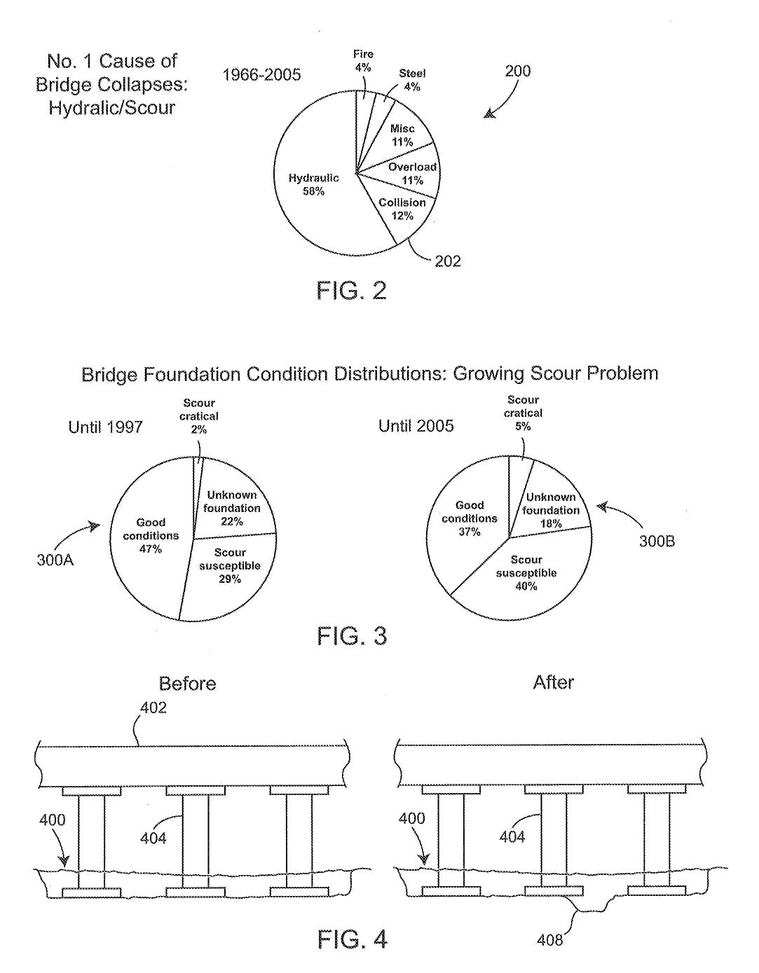

Bridge collapses due to scour often occur rapidly, sometimes within hours or days from the onset of scour critical conditions. FIG. 2 shows the various causes 200 of bridge collapses between 1966 and 2005. See Briaud, J. L., and Hunt, B. E., “Bridge Scour & the Structural Engineer,” Structures Magazine, December 2006, pp. 58-61. Hydraulic scour (at 58% as shown in FIG. 2) is the greatest cause 200 for bridge collapses. Bridge scour as a growing issue is clearly seen by comparing the 2005 and 1997 pie-charts 300A and 300B of FIG. 3. See Abutments,” NCHRP Report 396, Transportation Research Board, National Research Council, National Academy Press, Washington, D.C., 1997, p. 109 and see Hunt, B. E., “Practices for Monitoring Scour Critical Bridge,” NCHRP Report 205, Transportation Research Board, 2005, p. 8. Some of the consequences of bridge scour are shown in FIG. 4 in which a flood has eroded the riverbed 400 near a bridge 402 foundation 404 to cause a region of scour 408. Present methodologies with portable and fixed instruments, such as 1) inspection by divers, 2) probing rods, 3) ground penetrating radars (GPR), 4) boats, 5) sonar systems, 6) float-out devices, 7) magnetic sliding collars, 8) optical sensor systems, and 9) global positioning systems can hardly be applied when strong currents and/or floating debris 114 and/or ice exist in a river. These and other conditions therefore complicate proper application of such heretofore available techniques.

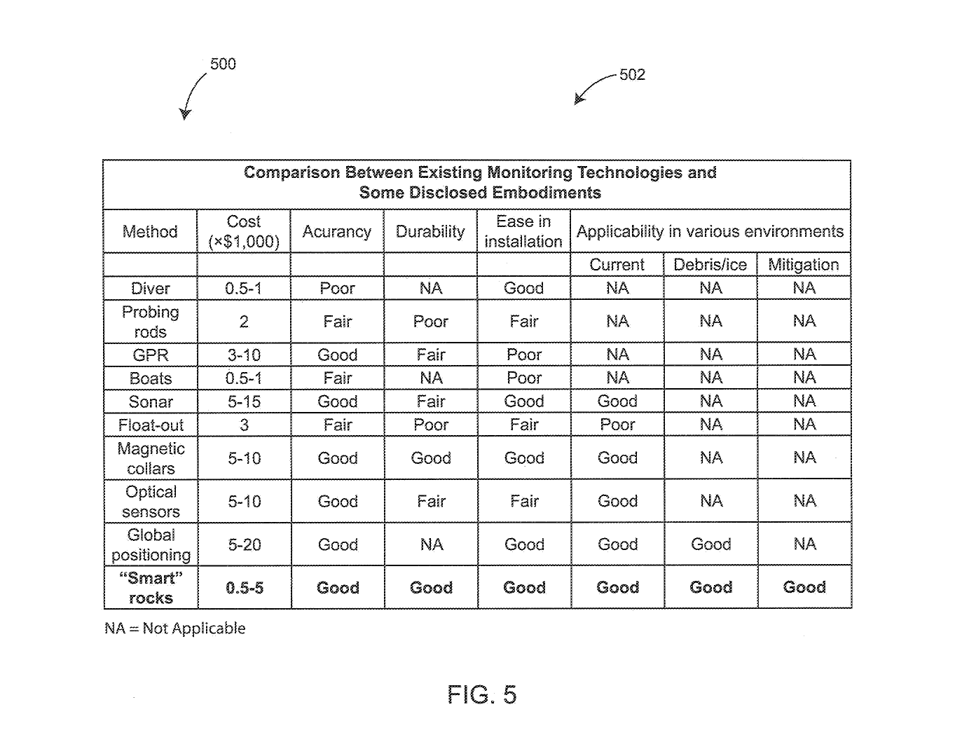

Furthermore, while a number of approaches exist for measuring scour-related conditions, previously available approaches suffer from certain disadvantages. FIG. 5 illustrates certain considerations with respect to monitoring and mitigating scour-related conditions with various types of systems including cost, accuracy, durability, ease of installation, applicability under certain condition, etc. See Federal Highway Administration (FHWA) and National Highway Institute (NHI), “Bridge Scour and Stream Instability Countermeasures: Experience, Selection, and Design Guidance,” Second Edition, Publication No. FHWA NHI 01-003, Hydraulic Engineering Circular No. 23, March 2001. See also Iowa Highway Research Board (IHRB), “An Illustrated Guide for Monitoring and Protecting Bridge Waterways against Scour,” Final Report No. 449, Project TR-515, March 2006. FIG. 5 also shows that some approaches or methods 500 can be applied with various results 502. However, previously available technologies can only be applied before and after scour-inducing events and cannot be used to mitigate scour-related conditions (unlike at least some of the sensors 106 disclosed herein).

### Sensors

Embodiments disclosed herein can be successfully applied to structures before, after, and even during scour-inducing events. Thus, knowledge of scour-related conditions can be obtained during all periods pertinent to the monitored structures. More particularly, scour sensors can be placed in regions 108 where scour is likely even during a time when scour susceptible and scour critical conditions might arise (for instance, during a flood). Various embodiments disclosed herein can therefore provide interested users with real-time information pertinent to understanding and evaluating changes that occur during such events (in addition to before-and-after comparisons of scour-related conditions).

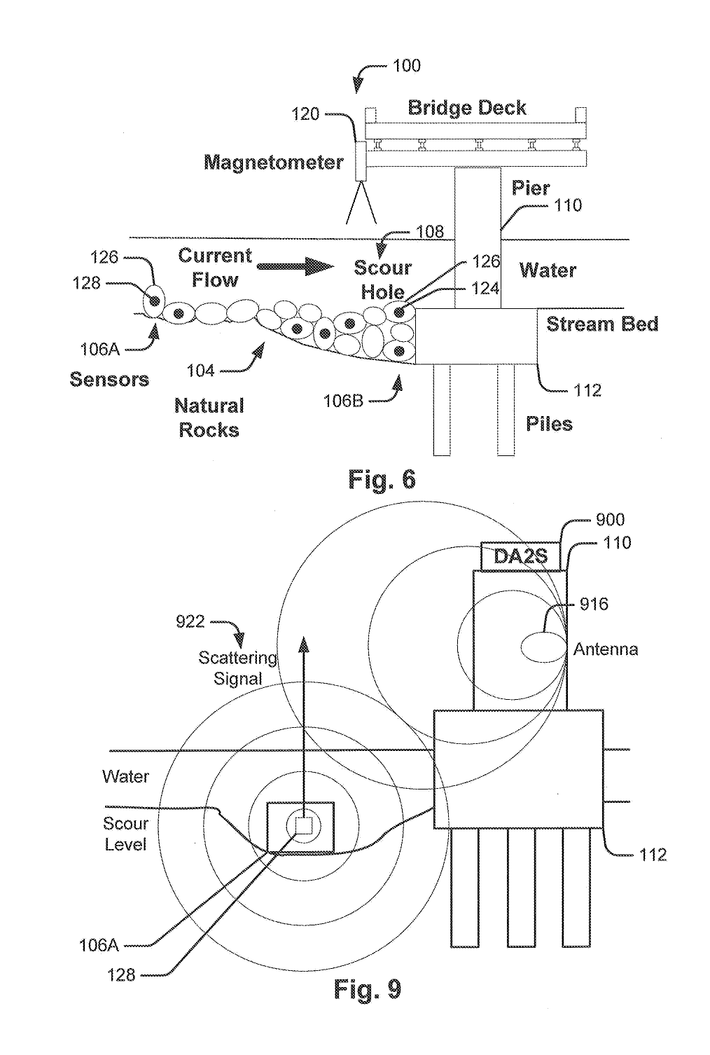

More specifically, systems of some embodiments include rock-like objects or concrete blocks with 1) embedded passive or active electronics, 2) a physically separate monitoring station or receiver, and 3) a wireless communication link there between so that related parameters (the locations of the sensors, the density of a group of sensors, their proximity to neighboring sensors, the acoustic noise or vibration level in the river, etc.) can be determined under strong flooding (or other) conditions. The information derived there from can enable scour evaluations and mitigation in real time. Embodiments disclosed herein include passive sensor embodiments and active sensor embodiments as illustrated by FIGS. 6-9 and elsewhere herein.

Real-Time Scour Mounitoring with Passive Sensors Group Dispersion Methods

Some passive sensor 106B embodiments involve creating a constant magnetic field 122 about each of (or some of) a group of passive sensors 106B. As disclosed further herein, the constant (with respect to the sensors 106) magnetic fields 122 can be used for locating them as a group (passive sensor group dispersion) or individually. In such embodiments, frequencies below about 10 MHz provide satisfactory communications through water. However, communications at other frequencies are within the scope of the disclosure. Magnetometers 120 can be used to measure the intensity of the combined magnetic fields 122 from the Earth, the passive sensors 106B, and the ferromagnetic parts around a bridge foundation or other structures.

In some passive embodiments, each passive sensor 106B includes a magnet 124 embedded in a housing 126 (see FIG. 6). These passive sensors 106B can be configured to have a density similar to that of naturally occurring rocks (or other filler material 104) used to mitigate scour. For instance, some passive sensors 106B (the embedded magnets and the housings combined) possess densities between about 1.2 g/cm̂3 and about 5.3 g/cm̂3 although other densities are also within the scope of the disclosure. Moreover, some housings can be shaped, dimensioned, etc. to mimic naturally occurring rocks in the locale of interest so that the passive sensors 106B move in response to flowing water in a manner similar to those naturally occurring rocks. Some embodiments provide more or less spherical sensors 106 with diameters of about 50 cm although sensors 106 of other dimensions (smaller and larger) and/or shapes are within the scope of the disclosure. For instance, in some embodiments, the sensors 106 are cone shaped with a center of gravity positioned to cause them to settle standing on their base. Thus, should scour remove the material underneath such sensors 106 they will tip over causing a detectable change in their orientation.

Various methods can be used to increase the magnetic fields 122 of passive sensors 106B. For instance, instead of using one passive sensor 106B, a group of passive sensors 106B can be placed near a bridge. Since the group will function like a large multi-pole magnet 124 (with the resulting magnetic field 122 reflecting contributions from each of the individual passive sensors 106B), the resulting magnetic field 122 can be used to detect the location of the group of passive sensors 106B. In addition, or in the alternative, the magnets 124 of a group of passive sensors 106B can be allowed to align themselves with the surrounding magnetic field by fixing the magnets 124 after the passive sensors 106B have been put in place. Not only might the alignment increase the magnetic field but it might also create a magnetic field which reflects the uniform orientation of the magnets.

One way to align these magnets 124 is to insert the magnets 124 into holes in the sensor housings. The holes can be shaped to correspond to the shapes of the magnets 124 while leaving gaps between the magnets 124 and the housings 126. These gaps can be filled with an epoxy or some other material that will eventually set within a selected time (such as 10-30 minutes) thereby fixing the magnets 124 in the housing. The resulting passive sensors 106B can be sealed and placed in the water at desired locations while the gap-filler material begins setting as shown in FIG. 6. It is noted here that, the gap-filler material can be selected so that by the time it sets, the magnets 124 in the as-placed sensors 106 have re-oriented themselves to align themselves as follows. In one embodiment, the centers of gravity of the magnets 124 are offset from the geometric center of the sensors 106 such that when the sensors 106 settle, the sensors 106 rotate with their heaviest portion positioned toward the bottoms of the sensors 106. Thus, if all of the magnets 124 of the sensors 106 have similar magnetic orientations (relative to the axes defined by the offsets of the geometric centers and center of gravities) then all of the sensors 106 will be magnetically aligned once they have settled and the gap-filler material sets.

In another embodiment, the magnets 124 align themselves with the surrounding magnetic field (often the Earth's magnetic field) as follows. In the current embodiment, the magnets 126 do not have an offset between their centers of gravity of the magnets 124 and the geometric centers of the sensors 106. Instead, the magnets 124 remain free to rotate in accordance with the surrounding magnetic field until the gap-filler material sets. Thus, once the magnets 126 are inserted into the sensors 106 and the sensors 106 settle, the magnets 126 rotate to align themselves with the surrounding magnetic field. Since the surrounding magnetic field will generally be that of the Earth, the individual magnets 126 will align with the Earth's magnetic field and therefore align with each other. Such sensors 106 can find application in situations where the sensors 106 near a particular structure are, or will be, dispersed from one another.

In the alternative, or in addition, steel blocks can be embedded into some passive sensors 106B to concentrate or focus pre-existing magnetic fields in their vicinity. Since the steel blocks cause no magnetic field of their own, it is likely that such sensors 106 can be used without orienting the steel blocks. Thus, in various embodiments, the magnets 124 of the sensors 106 can be aligned with each other thereby providing a magnetic field 122 reflecting that uniform alignment and which is stronger than it would be were the sensors 106 were not aligned.

Whether the passive sensors 106B are aligned or not, an instrument such as a magnetometer 120 can measure the resulting magnetic field 122 produced by the in-situ sensors 106 and changes to the same. For instance, when three-dimensional scour-related data is desired, several (for instance, three or more) magnetometers 120 can be used to enable real-time evaluation of bridge scour in terms of the locations, depths, and widths of scour-induced holes as well as other riverbed changes. This evaluation process can use an inverse transformation to identify the presence and location of the multiple-poles of various sensors 106 from the measured magnetic field data. That is, the magnetic signatures of each of the sensors 106 can be isolated and tracked to provide information regarding the scour-related erosion. Thus, the passive sensors 106B sense (by their presence in the resulting riverbed formations) the scour related erosion of the riverbed. The tracking of the passive sensors 106B can be performed continuously (providing real-time scour information if desired) or on a selected schedule. Moreover, the locations of the individual passive sensors 106B can be tracked, or the locations of the passive sensors 106B as a group can be tracked, to provide scour-related information.

At times it might be found desirable to add passive sensors 106B to a particular location. For instance, should some of the passive sensors 106B move away from the bridge, more sensors 106 can be added to the site. Indeed, in some cases, it might be useful to have about 10% to about 30% of the filler material 104 at a particular location be sensors 106 as shown in FIG. 6. Furthermore, because the passive sensors 106B can be configured to mimic naturally occurring rocks (or other filler materials 104) the placement of passive sensors 106B at the site can mitigate scour conditions.

Even so, during a scour-inducing event, the passive sensors 106B (and other objects and materials) in the water will likely be washed away or re-oriented. As a result, the combined magnetic field 122 (and/or the topology thereof) of the passive sensors 106B group will change in a corresponding fashion. Indeed, whereas a group of deployed sensors 106 will have an initial magnetic field 122 reflecting their originally deployed orientation (in line with the surrounding magnetic field, having an orientation of its internal DC magnetic field 122 parallel to the gravity-oriented magnetic field 122, etc.), a group of sensors 106 disturbed by a scour event will likely exhibit a changed magnetic field 122. In many cases, the signature of the magnetic field 122 of the passive sensors 106B will be randomized as compared to the original signature. As noted elsewhere herein, these changes can be measured. Thus, the data obtained from such sensors 106 can signify the onset and level, or degree, of bridge scour.

### Experimental Passive Sensor Systems

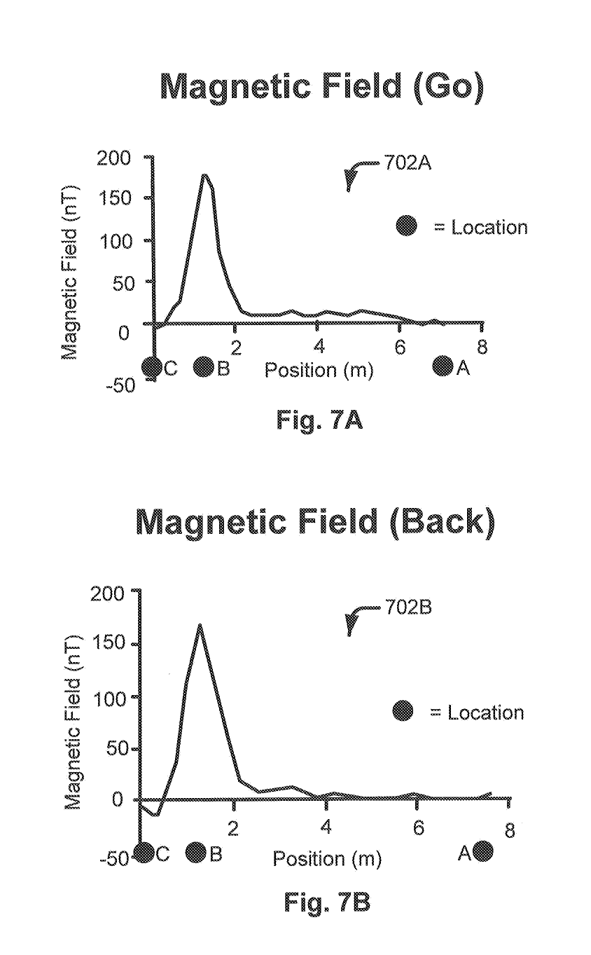

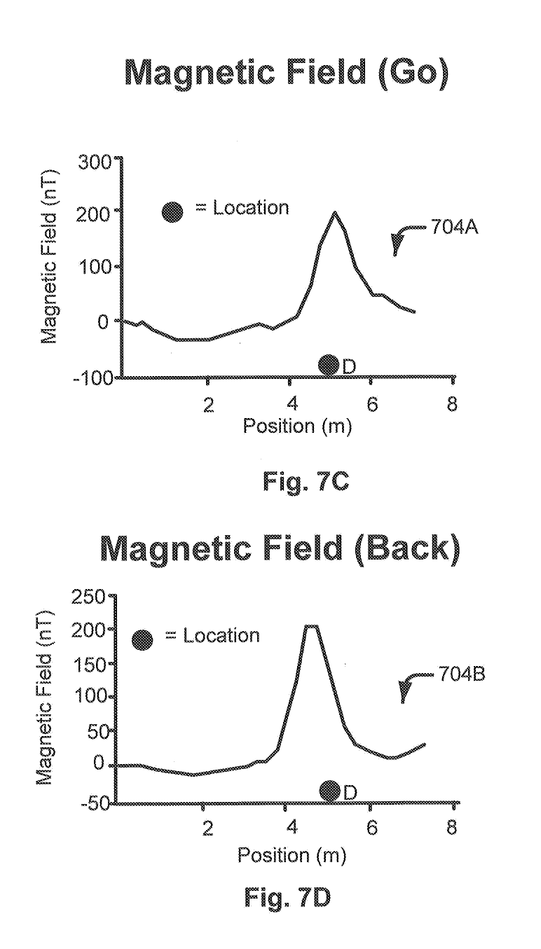

Initial tests of a passive system 100 were recently conducted at the Missouri University of Science and Technology (hereinafter “Missouri S&T). The experimental passive system 100 included magnets emulating the sensing unit of passive sensors 106B. In these tests, three groups of magnetic objects were tested at Missouri S&T and include a 6 cm magnet cube, 0.75 cm×15 cm×75 cm steel plates, and 15 cm-long #8 steel bars. Each of these magnetic objects was pulled in one direction and its position was detected with a model number G858 Geometrics magnetometer 120 (available from the Oyo Corporation USA in San Jose, Calif.). Plots 702A and 702B (of FIGS. 7A and 7C respectively) are representative of the data gathered. Note that the variation in the value between the two functions to the right of Point B was attributed to the effect of some small extraneous hand-held metallic objects being moved about near the experimental system.

FIGS. 7C and 7D also present the plots 704a and 704B of the intensity of a magnetic field as measured by the magnetometer as it was moved from a Point A to a Point B (7.6 m apart) and then returned to Point A while a 15 cm long #8 steel reinforcing bar was left at a fixed location D. As shown by FIG. 7 the plots 704 of the intensity of the magnetic field 122 drops with increasing distance between the magnetometer and the reinforcing bar. However, the position response function (the plots 704) of FIG. 7 clearly indicates the location of the bar with a spatial resolution of less than 1.0 m between two identical bars. The variation between the two plots 704 of the intensity arise primarily from hysteresis. The sensitivity of the magnetometer 120 to these objects demonstrates the ability of the experimental system 100 to measure the movement of metallic objects in a particular volume of interest.

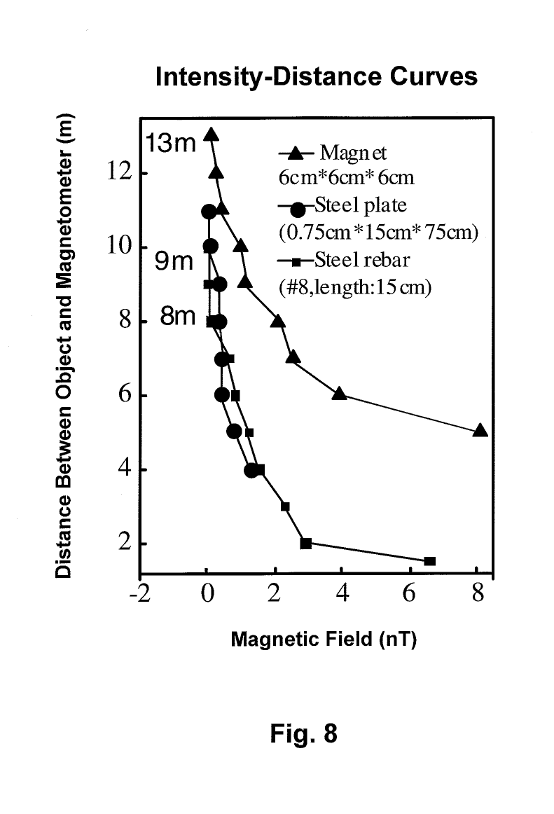

FIG. 8 presents plots 802 of the magnetic field intensity as a function of distance from several metallic items as measured by the experimental system 100. The magnetic objects included a magnet, a steel plate, and a piece of steel reinforcing bar. In the experimental system 100, a practical measurement distance happens to be between about 8 and about 13 m depending on the type of metallic objects in the region 108 of interest. These distances can be increased significantly with the use of larger metallic objects, stronger magnets, etc. Moreover, since magnetic fields 122 are generally unaffected by the presence of water, mud, sand, debris 114, and the like, passive systems 100 should work well in the field. However, slow changes of the Earth's magnetic field and the effect of other metallic parts (for instance, those moving with flowing water) might affect the magnetic field 122 created by various passive sensors 106B. However, passive systems 100 can be constructed to compensate for these and other environmental factors without undue experimentation. Moreover, where it is desired to receive stronger signals from a sensor 106, or group thereof, the receiver (and/or the associated magnetometers, antenna 116 or antennas 116, etc.) can be placed near the region 108 of interest (for instance, an area of a riverbed). In some embodiments, the receiver and/or one or more antennas 116 could be located under water near a submerged portion of the bridge foundation and made to be at least partially water-resistant.

The size, shape, and magnetic strength of the magnets in passive systems 100 can be optimized and calibrated in field applications on bridges and on other structures. Passive systems 100 can be used where measuring the location of a group of sensors 106 and a relatively simple system are desired. However, as disclosed herein, passive systems 100 can be used where measuring the location of individual sensors 106 is desired and/or in more complex situations.

Real-Time Monitoring with Active Sensor Positioning Methods

Several methods of measuring scour using active sensors 106A employing magneto-inductive communication are also disclosed herein. In some active embodiments, active sensors 106A include resonators 128 (see FIG. 6) instead of passive magnets in their housings. These resonators 128 can include devices and/or circuits capable of back scattering (or reflecting) an external magnetic or electromagnetic signal back (at least in part) in the direction from which the signal came. Such active sensors 106A can be used to measure the position of these active sensors 106A individually or as a group. More specifically, if it is desired to track the location of individual active sensors 106A, then the resonant frequencies of the resonators 128 can be selected so that each active sensor 106A has a resonator 128 with a frequency different from the others. Thus, each of the resonators 128 can be detected and tracked individually in some embodiments. Another embodiment uses passive back-scattering of an externally applied magnetic field to detect the movement of active sensors 106A. More specifically, the sensors 106 can contain a resonating circuit such that they communicate via passively back-scattering a magnetic field or electromagnetic field. In yet another embodiment, the sensors include a component(s) which, when the sensors 106 rotate, disables or destroys the resonator 128 (or magnet). For instance, the component could open the resonator 128 circuit or connect a magnetic short circuit path to the resonator 128 so that the external field decreases noticeable. For instance, the magnetic field could be reduced to a point that it effectively becomes undetectable. Such sensors 106 could be dropped into place and allowed to align themselves with the vertical (for instance). Gap-filler material in the sensors 106 could then be allowed to cure thereby leaving the sensors 106 in place and aligned. If sufficient scour occurs, some or all of the sensors 106 will rotate thereby disabling the magnet 124 or resonator 128 and causing a detectable change in the magnetic field 122 of the sensors 106. As a result, once the sensors 106 move or are re-orientated by more than some selected amount they no longer obscure the magnetic fields 122 of other sensors 106 (such as sensors 106 that might have been added after the sensors 106 that was moved or re-oriented). Again, this change in the magnetic field 122 can be detected and used to determine the corresponding change(s) in scour-related conditions.

Some active embodiments involve enabling magneto-inductive communications between active sensors 106A and a receiver. These communications can be used to identify and locate individual active sensors 106A at frequencies less than 10 MHz in some embodiments. However, higher communication frequencies are within the scope of the disclosure. In some embodiments communication methods such as magneto-inductive or sound-based methods can be used to query active sensors 106A regarding various scour-related conditions.

As with the passive sensors 106B disclosed herein, these active sensors 106A can be configured to have densities, shapes, sizes, etc. selected to mimic naturally occurring rocks (or other filler materials 104). Thus, active sensors 106A can be configured to respond to flowing water in a manner similar to that of naturally occurring rocks.

As illustrated in FIG. 9, a data acquisition/analysis system 900 of one embodiment transmits a magnetic signal 922 that is scattered by various active sensors 906A at selected frequencies. The magnetic signals 922 (as measured in magnitude and/or phase) received by a set of receiver antennas 916 (and/or magnetometers) can be used to determine the position of the individual active sensors 906A and, by comparison with their initial as-placed and subsequent locations, to monitor scour. Moreover, signal processing techniques can be applied to recover even weak or conflicting magnetic signals 922 from active sensors 906A. Antennas 916 of relatively larger size can also be used to increase the ability of active systems 900 to receive and analyze these magnetic signals 922.

The system of the current embodiment can use two communication methods although the disclosure is not limited to these communication methods. For one communication method, some sensors 906A use active magneto-inductive communication and contain a battery and timer. Thus, these particular sensors 906 can happen to transmit information at select times (for instance, every hour). However, the active communications of these sensors 906 could occur via ultrasonic or other types of transmitters. For the other communication method of the current embodiment, some sensors 906B use passive magneto-inductive communication via RF (radio frequency) signals. A transmitter (with a signal strength selected to provide communications between the transmitter and the sensors 906) transmits a signal to the sensors 906. These sensors 906 detect the transmitted signal and send it back to the transmitter (or receiver thereof). These sensors 906 can send the signal back to the transmitter by passive scattering, rectification, activation of an active circuit therein, etc. The active circuits of such sensors 906 can be similar to those found in RFID (radio frequency identification) tags.

In another embodiment, each sensor 106 includes a magneto-inductively powered rectifier. In such embodiments each sensor 106 detects an external signal and rectifies it to power a transmitter circuit that sends (on another frequency) a code for identifying that sensor 106. In addition to the code, these sensors 106 of the current embodiment can send information related to their physical orientations as measured by built-in accelerometers. Some of these built-in accelerometers can be configured to detect the Earth's gravitational field and to compare the orientation of the active sensors 106A (in which it is located) to that field. The resulting information can be transmitted and used to measure how much these active sensors 106A have moved or otherwise been reoriented.

In yet another embodiment, some or all of the sensors 106 include a battery and a timer. Some of these timers can draw power from the batteries and can trigger transmission bursts at selected times. As a wristwatch can run on a small battery for three years or longer, a sensor 106 with a timer operating on a battery can last for decades. Since each transmission burst can be of relatively short duration (less than 1 second), the integrated energy consumption will be low in spite of the occasionally increased current draw associated with these transmission bursts. Moreover, the underwater environment where such sensors 106 are expected to typically reside in operation is favorable for batteries (temperatures in such locations varies slowly) thus enabling long battery lives. Nonetheless, active sensors 106A of the current embodiment can be configured to minimize the energy consumption from self discharge and from standby circuits to extend the battery life of some active sensors 106A. It is expected that a battery life of 10 years is achievable for at least some active sensors 106A.

Active sensors 106A (see FIG. 1) of various embodiments include mechanisms, circuits, etc. which allow a user to select from a variety of transmission scenarios. Three such embodiments include:
An embodiment in which active sensors 106A are activated by an external magnetic, magneto-inductive, radio frequency, ultrasonic or other type of signal and when activated transmit their IDs, and other information at the same frequency as the eternal signal or at some other frequency.
Another embodiment wherein the active sensors 106A include timers and transmit their ID, and other information regularly, such as hourly; and
Yet another embodiment in which each active sensor 106A is activated by an accelerometer and transmits its ID, and/or other information as the sensor rotates or moves (with a timer determining how long it remains transmitting thereafter the movement or reorientation).

The latter variant can be applied to automatically alert an engineer-in-charge (or other users) to evolving scour-related information through an Internet or telephony connection or other telecommunication techniques. Such active sensors 106A could transmit a variety of information related to scour including the distance to other sensors 106 from itself and/or acoustic noise at its location.

Preliminary simulations into the signal-to-noise ratio show the possibility of communications through water and between active sensors 106A and receivers at frequencies below 1 MHz (although communication at higher frequencies is also included in the scope of the disclosure). In a non-optimized scenario, communication between an active sensor 106 at a depth of 2 m in fresh water was achieved with a receiver using two 0.5 m×0.5 m antennas 116. One antenna 116 of this system 100 was placed 5 m to the left and the other antenna 116 was placed 5 m to the right of the sensors 106. Performance of other systems 100 can be improved by using larger antennas 116, more turns, higher power, and/or various signal processing techniques. Alternatively, the antenna(s) 116 may be installed around a bridge pier 110 close to the potential scour region 108 to minimize the communication distance.

As disclosed herein, different types of sensors 106 (with passive structures inside, with semi-active structures inside, and with batteries or other active components inside) are provided in this disclosure. The ability to communicate with those sensors 106, to locate the sensors 106, and the complexity and life spans of the systems 100 can be factors to consider in selecting a system 100 for scour measurement and/or mitigation applications.

The size of the antennas 116, the number of antennas 116 and their position relative to the potential scour region 108 can influence the ability to communicate with and locate various types of sensors 106. If the antennas 116 are embedded into piers 110 (for bridges under construction or those being retrofitted), they can be close to the sensors, thus improving the communication with, and the localization, of such sensors 106.

Signal processing is another way to improve the quality of the information received from the sensors. There are many ways to process signals and extract information even from weak or conflicting signals. Any of these and other techniques can be employed to improve the recovery of the information transmitted from (or otherwise provided by) sensors 106 in a given system 100.

If a magneto-inductive communication is considered, the salinity (and therefore conductivity) of the water can influence the ability to communicate magneto-inductively with, and to locate, sensors 106 deployed in such environments. Typically, lower communications frequencies allow for better communication through salt water. Moreover, systems 100 of some embodiments can use magneto-inductive, sonic, ultrasonic, electromagnetic, and other methods of communicating scour-related information to the receiver. Thus it is possible that different system 100 designs can be optimized for different situations based on tradeoffs between antenna size, antenna positioning, communications frequency(s), power, reliability, etc.

Recently, some electromagnetic simulations were conducted at Missouri S&T to evaluate the feasibility of active sensor positioning. The results indicate that it is possible to reconstruct the paths of individual sensors 106 during the scour process. Doing so can entail integrating the signals from one or more accelerometers on the sensors 106 of interest. In addition, or in the alternative, the overall movement of a particular sensor 106 or groups of sensors 106 can be monitored with active systems 100.

Sensors 106, systems 100, and their wireless sensing networks of various embodiments provide non-limiting advantages over technologies heretofore available. First, the architecture of self-inductive sensors 106 and their wireless sensing networks can be relatively simple. They can be easy to install and the data acquired there from can be easy to process. One pertinent measurement principle used in such embodiments is based on classical magnetic field theory. In some embodiments an inverse transform is performed to identify the presence of sensors 106 from measured magnetic field data. Systems 100 of many embodiments require minimal (or no) professional services to install and operate in practical applications. Moreover, systems 100 can be installed at the time of foundation construction, when scour monitoring is desired, during scour events, and/or during scour mitigation efforts.

Second, sensors 106 can be durable and applicable to environments with high water velocities, debris 114 or ice entrained in a current. With the protection offered from the bodies or housings 126 of some sensors 106, the embedded self-inductive devices can survive various harsh environments and can be operational throughout the life span of an engineering structure (for instance, bridges or offshore platforms).

Third, sensors 106 can be multi-functional. More particularly, systems 100 can combine the scour monitoring and scour protection/mitigation into one integrated implementation. Systems 100 of embodiments can be applied to the bottom of the bodies of water formed from soil, rocks, sand, other materials, or various combinations thereof thereby extending the application range of systems 100 beyond that of previously available technologies.

Fourth, systems 100 can be small, portable, and easy to deploy. For instance, a group of sensors 106 and a magnetometer 120 (or other receiver) can be configured to fit in a back pack which can be carried to a place near, or at, a potential scour site. The magnetometer 120 can be deployed and the sensors 106 dropped or otherwise placed in a region 108 of interest. The initial magnetic field 122 and changes thereto can be measured with the magnetometer 120 with data analysis occurring at the same (or some other) time. Nonetheless, the deployment of systems 100 of the current embodiment can take only a few moments or less.

Next, such systems 100 as those disclosed herein can be inexpensive. According to the Hydrologic Engineering Center (HEC), the instrument costs of various scour monitoring technologies are approximately: $2000 for physical probes, $15,000 for a portable sonar survey grade system, $5,000-$15,000 for a fixed sonar, $7,500-10,000 for a sounding rod, $5,000-10,000 for a magnetic sliding collar, $3,000 for a float-out system or $500/float-out, $10,000 for traditional land survey, and $5,000 and $20,000 for Global Position System (GPS) of sub-meter and centimeter accuracy, respectively. See Lagasse, P. F., Richardson, E. V., and Schall, J. D., “Instrumentation for Monitoring Scour at Bridge Piers and Abutments,” NCHRP Report 396, Transportation Research Board, National Research Council, National Academy Press, Washington, D.C., 1997, p. 109. In comparison with these previously available technologies, a system of twenty sensors 106 of some embodiments might cost as little as $1,000.

Thus, embodiments provide solutions to the largest cause of bridge collapses in the United States due at least in part to their ease of use, low or non-existent maintenance considerations, cost effectiveness, and/or other considerations. Moreover, sensors 106 of various system themselves can be used to mitigate scour conditions since they can be configured to have pertinent characteristics (for instance, density) similar to those of naturally occurring rocks and/or other objects sometimes used to mitigate scour-related conditions. Another advantage provided by embodiments is that some systems 100 can be placed on and/or near existing bridges whereas previously available systems 100 and/or methods need special installations on the bridge and/or under the water.

### CONCLUSION

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method comprising:
placing a sensor with a density about equal to or greater than the density of water at a location where the water is expected to flow thereby potentially causing the scour wherein the sensor comprises an object configured to alter a magnetic field in a vicinity of the sensor responsive to a change in a scour-related condition at about the location of the sensor;
allowing a change to occur in the scour-related condition at about the location of the sensor; and
allowing the sensor to cause a wireless signal to propagate through the water to convey data regarding the change in the scour-related condition at about the location of the sensor.

2. The method of claim 1 wherein the sensor further comprises a signal generator in communication with the object configured to alter the magnetic field and wherein the signal generator is configured to cause the wireless signal.

3. The method of claim 2 wherein the signal generator is a selected from the group consisting of a passive magnet, an active magnet, a magnetic resonator, an accelerometer or a combination thereof.

4. The method of claim 2 wherein the object configured to alter the magnetic field is the signal generator.

5. The method of claim 1 further comprising receiving the wireless signal and correlating the data conveyed to determine the change in the scour-related condition.

6. The method of claim 1 further comprising creating the sensor by placing the object configured to alter a magnetic field in a housing of the sensor and filling a gap between the object configured to alter a magnetic field and the housing with a settable gap-filler material.

7. The method of claim 1 wherein the density of the sensor is between about 1.2 g/cm̂3 and about 5.3. g/cm̂3.

8. A system for measuring hydraulic scour near a foundation of a bridge and caused by water flowing near the bridge, the system comprising:
at least one sensor including a magnetic object submerged in the water and possessing a density of between about 1.2 g/cm̂3 and about 5.3. g/cm̂3;
a magnetometer positioned at least near the bridge and being configured to sense a magnetic field of the magnetic object through the water and to output an indication of the magnetic field of the magnetic object through the water; and
a circuit in communication with the magnetometer and being configured to determine a scour-related condition based on the indication of the magnetic field of the magnetic object as sensed through the water.

9. The system of claim 8 wherein the sensor further comprises an accelerometer to sense an acceleration of the sensor and wherein the sensor further comprises a transmitter to transmit data regarding the sensed acceleration to the circuit.

10. The system of claim 9 wherein the sensor is adapted to output the indication of the magnetic field when the accelerometer senses more than a threshold amount of movement of the sensor.

11. A system for measuring scour, the system comprising:
at least one sensor adapted to be placed in a region where water is expected to flow thereby causing scour and to sense a condition related to the scour;
a signal generator configured to generate a wireless signal to convey data regarding the as-sensed scour-related condition and for receipt by a receiver; and
the sensor and the signal generator together possessing a density about equal to or greater than the density of the water.

12. The system of claim 11 wherein the sensor is the signal generator.

13. The system of claim 11 further comprising the receiver.

14. The system of claim 13 wherein the receiver further comprises a device selected from the group consisting of an antenna, a magnetometer, an ultrasonic sensor, or a combination thereof.

15. The system of claim 11 wherein the density of the coupled sensor and signal generator is between about 1.2 g/cm̂3 and about 5.3. g/cm̂3.

16. The system of claim 11 wherein the sensor is a magnetic object.

17. The system of claim 11 wherein the sensor and signal generator are coupled by a housing.

18. The system of claim 17 wherein a location of the magnetic object is offset from a center of gravity of the coupled sensor, signal generator, and housing.

19. The system of claim 17 wherein the housing is approximately conic in shape.

20. The system of claim 17 further comprising gap-filler material between the housing and the magnetic object.
